(19) United States
(12) Patent Application Publication
(10) Pub. No.: US 2017/0273188 A1
(43) Pub. Date: Sep. 21, 2017

(54) Flexible Copper Clad Laminate Having High Peel Strength and Manufacturing Method Thereof

(71) Applicant: Guangzhou Fang Bang Electronics Co., LTD., Guangzhou, Guangdong (CN)

(72) Inventor: Zhi Su, Guangzhou (CN)

(21) Appl. No.: 15/318,946

(22) PCT Filed: Dec. 19, 2014
(86) PCT No.: PCT/CN2014/094379

§ 371 Date: Dec. 14, 2016

(30) Foreign Application Priority Data
Dec. 2, 2014 (CN) 201410723337.5

(51) Int. Cl. H05K 3/02; B32B 15/20; B32B 27/08; H05K 3/28; H05K 1/03; H05K 3/10; H05K 1/02; B32B 15/08; H05K 1/09

(52) U.S. Cl. CPC H05K 3/022; B32B 15/08; B32B 15/20; B32B 27/08; H05K 1/09; H05K 1/036; H05K 1/0373; H05K 3/10; H05K 1/028; H05K 3/282; B32B 2457/08; H05K 2203/0307

(57) ABSTRACT

The disclosure discloses a flexible copper clad laminate (FCCL) having a high peel strength and a manufacturing method thereof. The FCCL includes: an organic polymer film layer (1), an adjusting layer (2), a transition layer (3) and a copper layer (4).

### TECHNICAL FIELD

The disclosure relates to a Flexible Copper Clad Laminate (FCCL) having a high peel strength and a manufacturing method thereof.

### BACKGROUND

A Flexible Printed Circuit (FPC), serving as a special base material connected to an electronic component, has excellent properties of lightness, thinness, structure diversity, bending resistance and the like. It may be widely applied to the high-end fields of foldable mobile phones, liquid crystal displays, notebook computers and band carrier Integrated Circuit (IC) packaging substrates.

A traditional FCCL mainly refers to an adhesive type product, is a three-layer structure composed of copper, an adhesive and a Polyimide (PI) film, and is called as a 3L-FCCL for short. The adhesive in the 3L-FCCL is epoxy, the thermal stability being poorer than that of a PI base material, which results in reduction of the thermal stability and dimensional stability of the FCCL and thickening of the base material. Recently, with the rapid development of the electronic industry, electronic products further develop to be small-sized, light-weighted and highly dense in assembly. The industry begins to pay close attention to research and application of an adhesive-free FCCL. Compared with an adhesive FCCL, the adhesive-free FCCL does not have an adhesive, so as to be high in heat resistance, high in dimensional stability and high in reliability. Meanwhile, the adhesive-free FCCL is very thin and high in bending resistance.

At present, the adhesive-free FCCL is mainly manufactured by the following several methods:

1) A coating method—coating the surface of a copper foil with polyimide, and performing curing molding;

2) A laminating method—laminating the copper foil with the polyimide at high temperature; and

3) A plating method—forming a conductive bottoming layer on the surface of a polyimide film, and then forming a copper metal layer.

In the above three methods, a double-faced plate cannot be prepared using only the coating method. The laminating method is diversified in structure and high in peel strength, but the copper foil is limited in thickness, an ultrathin copper foil cannot be adopted, if the ultrathin copper foil is adopted, folds are easily caused or even ruptures are generated during coating or laminating, such that application to high-grade precise electronic products such as liquid crystal (plasma) displays and liquid crystal (plasma) televisions based on a High Density Interconnect (HDI) technology and a Chip on Flex (COF) technology is certainly limited. A sputtering method may prepare a single-faced plate and a double-faced plate, the copper foil may be very thin, the thickness may be customized, and the sputtering method is applied to an ultrathin line and is the most promising method for preparing an adhesive-free FCCL.

The several adhesive-free FCCLs formed by plating methods are as follows.

The inventive patent (Publication Number: CN1329186C) entitled “Preparation method for FCCL” discloses an adhesive-free FCCL. The structure is that a conductor layer is plated on the surface of a polymer film in a vacuum manner, and then metal layers are continuously and compositely plated. The method has the advantages that the metal layers may be very thin and uniform in thickness, but lower in peel strength, and use requirements cannot be met.

The structure of a product disclosed by the inventive patent (Publication Number: CN1124203C) entitled “Adhesive-free flexible layer complex product and manufacturing method thereof” is that a plasma treatment surface is formed by contact between at least one surface of a polymer film and a plasma containing ionized oxygen generated by a non-plating metal cathode. A nickel or nickel alloy bonding layer is deposited on the surface of the plasma, and a copper layer is deposited on the nickel bonding layer. The disclosure improves the peel strength of an adhesive-free FCCL using a plasma treatment technology. However, the peel strength is not ideal, and cannot meet use requirements. The treated surface is unstable, and the disclosure is not suitable for large-batch coiled production.

The inventive patent (Publication Number: CN102717554A) entitled “Two-layer FCCL” discloses a two-layer structure FCCL having a copper layer covering the surface of a polymer thin film. The disclosure improves, before a copper layer is formed, the peel strength of an adhesive-free FCCL by ion injection, but the peel strength is only 6-7N/cm, and the FCCL cannot be used.

In the above three specific methods, a conductor bottoming layer is directly formed on the surface of a polymer film, and then a copper layer is formed. The peel strength of an FCCL obtained by the method is extremely low to be only 3-5N/cm. In order to increase a binding force between an organic polymer film and a metal layer, the surface of the polymer film is subjected to plasma treatment, and a bottoming layer and a metal layer are formed again. Or, before the metal layer is formed, an ion injection process is added, but the above methods do not solve the problem of low peel strength of an adhesive-free FCCL.

In order to solve the technical bottlenecks of the plating method, improvement of the peel strength of an adhesive-free FCCL is urgently demanded.

### SUMMARY

The disclosure is intended to provide an FCCL having a high peel strength and a manufacturing method thereof.

The technical solutions adopted by the disclosure are as follows.

An FCCL having a high peel strength includes the following layer structures: an organic polymer film layer, an adjusting layer disposed on at least one surface of the organic polymer film layer, a transition layer disposed on the surface of the adjusting layer, and a copper layer disposed on the surface of the transition layer, wherein the number of the transition layer is one or more.

The thickness of the organic polymer film layer is 5-125 microns. The organic polymer film layer is made from at least one of a polyimide, a polyethylene terephthalate, a polybutylene terephthalate, a polysulfone, polyphenylene sulfide, a polyether ether ketone, a polyphenyl ether, a polytetrafluoroethylene, a liquid crystal polymers and a polyparabanic acid.

The adjusting layer is one of adjusting layers listed from I to VII as follows.

I) The adjusting layer is made from at least one of thermoplastic polyimides, modified epoxy resins, modified acrylic acids, modified polyurethanes and modified phenolic resins, the thickness being 0.05-30 microns.

II) The adjusting layer is made from a mixture of a matrix resin and a filler, the thickness of the adjusting layer being 0.05-30 microns. The matrix resin is at least one of thermoplastic polyimides, modified epoxy resins, modified acrylic acids, modified polyurethanes and modified phenolic resins. The filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin. The volume percentage of the filler to the resin is 1-50%.

III) The adjusting layer is made from a resin and a catalyst solution, the thickness of the adjusting layer being 0.05-30 microns. The resin is at least one of thermoplastic polyimides, modified epoxy resins, modified acrylic acids, modified polyurethanes and modified phenolic resins.

IV) The adjusting layer is made from at least one of a coupling agent, a surfactant, an organic silicon and an organic low-polymer surface modifier, the thickness of the adjusting layer being 10-100 nm.

V) The adjusting layer is a superposed layer of the adjusting layer I and the adjusting layer IV, the thickness being 0.05-30 microns.

VI) The adjusting layer is a superposed layer of the adjusting layer II and the adjusting layer IV, the thickness being 0.05-30 microns.

VII) The adjusting layer is a superposed layer of the adjusting layer III and the adjusting layer IV, the thickness being 0.05-30 microns.

When the transition layer is a single layer, the thickness of the transition layer is 0.01-0.5 microns. When the number of the transition layer is more than one, the total thickness of the transition layer is 0.01-0.5 microns. The transition layer is made from one of a metal material, ferrite and a carbon nanotube, wherein the metal material is one of these metal elementary substances: an aluminium, a titanium, a zinc, an iron, a nickel, a chromium, a cobalt, a copper, a silver, a gold and a molybdenum, or an alloy formed by at least two of these metal elementary substances. A forming mode of the transition layer is selected from a chemical plating mode, a physical vacuum deposition (PVD), a chemical vapour deposition (CVD), an evaporation plating, a sputter plating, an electroplating or a composite process. A forming mode of the copper layer is selected from a chemical plating mode, a PVD, a CVD, an evaporation plating, a sputter plating, an electroplating or a composite process.

A manufacturing method for an FCCL having a high peel strength includes the steps as follows:
1) An adjusting layer is formed on at least one surface of an organic polymer film layer.
2) One or more transition layers are formed on the surface of the adjusting layer.
3) A metal copper layer is formed on the surface of the transition layer.

A manufacturing method for an FCCL having a high peel strength includes the steps as follows:
1) At least one surface of an organic polymer film layer is modified.
2) An adjusting layer is formed on at least one surface of the modified organic polymer film layer.
3) One or more transition layers are formed on the surface of the adjusting layer.
4) A metal copper layer is formed on the surface of the outermost transition layer.

A manufacturing method for an FCCL having a high peel strength includes the steps as follows:
1) An adjusting layer is formed on at least one surface of an organic polymer film layer.
2) The surface of the adjusting layer is modified.
3) One or more transition layers are formed on the modified surface of the adjusting layer.
4) A metal copper layer is formed on the surface of the transition layer.

A manufacturing method for an FCCL having a high peel strength includes the steps as follows:
1) At least one surface of an organic polymer film layer is modified.
2) An adjusting layer is formed on at least one surface of the modified organic polymer film layer.
3) The surface of the adjusting layer is modified.
4) One or more transition layers are formed on the modified surface of the adjusting layer.
5) A metal copper layer is formed on the surface of the transition layer.

A surface modification method for the organic polymer film layer or the adjusting layer may be selected from a chemical etching process, a plasma treatment process, an ion injection process, a surface grafting process, an ion beam irradiation process, an excimer laser etching process or a composite process thereof.

A manufacturing method for an FCCL having a high peel strength further includes the steps as follows. After the metal copper layer is formed, an anti-oxidation protection layer is formed on the surface of the metal copper layer as required. Or, the metal copper layer is roughened.

The disclosure has the beneficial effects as follows. The disclosure forms an FCCL having a higher peel strength by means of a plating method, and the thickness of a copper foil of the FCCL may be very thin.

Specifically speaking, an adjusting layer is formed on an organic polymer film, the roughness of the organic polymer film is controlled and the surface hydrophilicity of the organic polymer film is changed by means of the adjusting layer, the organic polymer film is modified in a physical addition mode, and the peel strength of an FCCL is improved. Compared with a conventional subtraction surface treatment method (such as chemical etching, etc.), the manufacturing method of the disclosure improves the peel strength of the FCCL to a greater extent. Meanwhile, the physical and mechanical properties of the organic polymer film are not excessively destroyed, and the FCCL which is high in peel strength, uniform and customizable in copper foil thickness, suitable for an ultra-fine line may be prepared.

### BRIEF DESCRIPTION OF THE DRAWINGS

FIG. 1 is a layer structure diagram of an FCCL according to the disclosure.

FIG. 2 is a structural diagram of another FCCL having a high peel strength according to the disclosure.

### DETAILED DESCRIPTION OF THE EMBODIMENTS

An FCCL having a high peel strength is composed of the following layer structures: an organic polymer film layer, an adjusting layer disposed on at least one surface of the organic polymer film layer, a transition layer disposed on the surface of the adjusting layer, and a copper layer disposed on the surface of the transition layer, wherein the number of the transition layer is one or more. Preferably, the copper layer is a roughened copper layer.

Or, the FCCL is composed of the following layer structures: an organic polymer film layer, an adjusting layer disposed on at least one surface of the organic polymer film layer, a transition layer disposed on the surface of the adjusting layer, a copper layer disposed on the surface of the transition layer, and an anti-oxidation protection layer disposed on the surface of the copper layer, wherein the number of the transition layer is one or more. Preferably, the copper layer is a roughened copper layer.

The thickness of the organic polymer film layer is 5-125 microns. The organic polymer film layer is made from at least one of a polyimide, a polyethylene terephthalate, a polybutylene terephthalate, a polysulfone, a polyphenylene sulfide, a polyether ether ketone, a polyphenyl ether, a polytetrafluoroethylene, a liquid crystal polymers and a polyparabanic acid. Preferably, the thickness of the organic polymer film layer is 5-50 microns.

The adjusting layer is one of adjusting layers listed from I) to VII) as follows.

I) The adjusting layer is made from at least one of thermoplastic polyimides, modified epoxy resins, modified acrylic acids, modified polyurethanes and modified phenolic resins, the thickness being 0.05-30 microns, 0.5-5 microns, preferably.

II) The adjusting layer is made from a mixture of a matrix resin and a filler, the thickness of the adjusting layer being 0.05-30 microns, 0.5-6 microns, preferably. The matrix resin is at least one of thermoplastic polyimides, modified epoxy resins, modified acrylic acids, modified polyurethanes and modified phenolic resins. The filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin. The volume percentage of the filler to the resin is 1-50%, 3-20%, preferably.

III) The adjusting layer is made from a resin and a catalyst solution, the thickness of the adjusting layer being 0.05-30 microns, 0.5-10 microns, preferably. The resin is at least one of thermoplastic polyimides, modified epoxy resins, modified acrylic acids, modified polyurethanes and modified phenolic resins.

Preferably, the catalyst solution is a solution formed by salts of an iron group element and/or a platinum group element and an organic solvent.

Further preferably, the catalyst solution is a solution formed by palladium salt and ethyl alcohol or acetone. A manufacturing method for the adjusting layer includes: mixing a resin and an ethyl alcohol or acetone solution of the palladium salt, curing at 160-180 DEG C, soaking a plate with the cured adjusting layer in a reducing agent solution (such as a sodium hypophosphite solution) at 60-80 DEG C, treating for 1-60 min, and taking out for drying.

Thus, some zero-valence Pds at least exist on the surface of the resin, and therefore, when the transition layer is formed on the adjusting layer, a binding force between the adjusting layer and the transition layer may be enhanced.

IV) The adjusting layer is made from at least one of a coupling agent, a surfactant, an organic silicon and an organic low-polymer surface modifier, the thickness being 10-100 nms, 10-50 nms, preferably.

V) The adjusting layer is a superposed layer of the adjusting layer I and the adjusting layer IV, the thickness being 0.05-30 microns, 0.5-5 microns, preferably.

VI) The adjusting layer is a superposed layer of the adjusting layer II and the adjusting layer IV, the thickness being 0.05-30 microns, 0.5-6 microns, preferably.

VII) The adjusting layer is a superposed layer of the adjusting layer III and the adjusting layer IV, the thickness being 0.05-30 microns, 0.5-10 microns, preferably.

When the transition layer is a single layer, the thickness of the transition layer is 0.01-0.5 microns, 0.05-0.3 microns, preferably. When the number of the transition layer is more than one, the total thickness of the transition layer is 0.01-0.5 microns, 0.05-0.3 microns, preferably. The transition layer is made from one of a metal material, ferrite and a carbon nanotube, wherein the metal material is one of these metal elementary substances: an aluminium, a titanium, a zinc, an iron, a nickel, a chromium, a cobalt, a copper, a silver, a gold and a molybdenum, or an alloy formed by at least two of these metal elementary substances. A forming mode of the transition layer is selected from a chemical plating mode, a PVD, a CVD, an evaporation plating, a sputter plating, an electroplating or a composite process. A forming mode of the copper layer is selected from a chemical plating mode, a PVD, a CVD, an evaporation plating, a sputter plating, an electroplating or a composite process thereof. The thickness of the copper layer is 0.5-50 microns, 5-20 microns, preferably.

Correspondingly, a manufacturing method for an FCCL having a high peel strength includes the steps as follows:
1) An adjusting layer is formed on at least one surface of an organic polymer film layer.
2) One or more transition layers are formed on the surface of the adjusting layer.
3) A metal copper layer is formed on the surface of the transition layer.

Correspondingly, a manufacturing method for an FCCL having a high peel strength includes the steps as follows:
1) At least one surface of an organic polymer film layer is modified, and an adjusting layer is formed on at least one surface of the modified organic polymer film layer. Preferably, the adjusting layer is formed on the modified surface of the modified organic polymer film layer.
2) One or more transition layers are formed on the surface of the adjusting layer.
3) A metal copper layer is formed on the surface of the outermost transition layer.

Correspondingly, a manufacturing method for an FCCL having a high peel strength includes the steps as follows:
1) An adjusting layer is formed on at least one surface of an organic polymer film layer.
2) The surface of the adjusting layer is modified.
3) One or more transition layers are formed on the modified surface of the adjusting layer.
4) A metal copper layer is formed on the surface of the transition layer.

Correspondingly, a manufacturing method for an FCCL having a high peel strength includes the steps as follows:
1) At least one surface of an organic polymer film layer is modified.
2) An adjusting layer is formed on at least one surface of the modified organic polymer film layer. Preferably, the adjusting layer is formed on the modified surface of the modified organic polymer film layer.
3) The surface of the adjusting layer is modified.
4) One or more transition layers are formed on the modified surface of the adjusting layer.
5) A metal copper layer is formed on the surface of the transition layer.

A surface modification method for the organic polymer film layer or the adjusting layer is selected from a chemical etching process, a plasma treatment process, an ion injection process, a surface grafting process, an ion beam irradiation process, an excimer laser etching process or a composite process thereof.

A manufacturing method for an FCCL having a high peel strength may further include the steps as follows according to actual requirements. After the metal copper layer is formed, an anti-oxidation protection layer is formed on the surface of the metal copper layer. Or, the metal copper layer is roughened.

Two of the structures of the FCCL of the disclosure are illustrated below in conjunction with the figures.

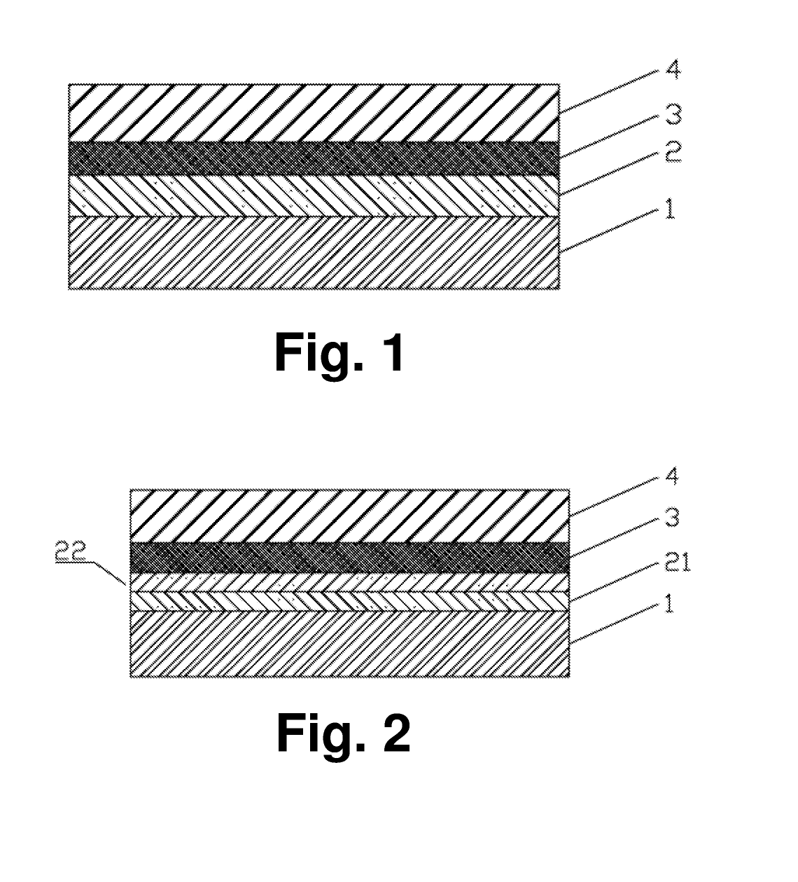

FIG. 1 shows a layer structure diagram of an FCCL according to the disclosure. An adjusting layer 2 is disposed on the surface of one side of an organic polymer film layer 1, a transition layer 3 is disposed on the surface of the other side of the adjusting layer 2, and a copper layer 4 is disposed on the surface of the other side of the transition layer 3. That is, the adjusting layer, the transition layer and the copper layer are formed on the surface of one side of the organic polymer film layer sequentially.

FIG. 2 shows another layer structure diagram of an FCCL according to the disclosure. A first adjusting layer 21 is disposed on the surface of one side of an organic polymer film layer 1, a second adjusting layer 22 is disposed on the surface of the other side of the first adjusting layer 21, a transition layer 3 is disposed on the surface of the other side of the second adjusting layer 22, and a copper layer 4 is disposed on the surface of the other side of the transition layer 3. That is, the first adjusting layer, the second adjusting layer, the transition layer and the copper layer are formed on the surface of one side of the organic polymer film layer sequentially.

Specially, the first adjusting layer 21 is selected from the adjusting layer described in I, and the second adjusting layer 22 is the adjusting layer described in IV; or, in reverse, the first adjusting layer 21 is the adjusting layer described in IV, and the second adjusting layer 22 is the adjusting layer described in II.

Or, the first adjusting layer 21 is selected from the adjusting layer described in II, and the second adjusting layer 22 is the adjusting layer described in IV; or, in reverse, the first adjusting layer 21 is the adjusting layer described in IV, and the second adjusting layer 22 is the adjusting layer described in II.

Or, the first adjusting layer 21 is the adjusting layer described in IV, and the second adjusting layer 22 is the adjusting layer described in III.

Certainly, as above, there may be more than one transition layer of the FCCL of the disclosure, the total thickness of the transition layer being 0.01-0.5 micron (0.05-0.3 micron, preferably). In addition, FIG. 1 and FIG. 2 only display the situation when the adjusting layer, the transition layer and the copper layer are disposed on one of the surfaces of the organic polymer film layer sequentially. Actually, the adjusting layer, one or more the transition layers and the copper layer may be disposed on the surface of each of two sides of the organic polymer film layer of the disclosure sequentially.

The disclosure is further illustrated below in conjunction with specific embodiments.

### Embodiment 1

An FCCL having a high peel strength includes an organic polymer film layer, an adjusting layer being disposed on at least one surface of the organic polymer film layer, one or more transition layers being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) An adjusting layer is formed on at least one surface of an organic polymer film layer. The thickness of the organic polymer film layer is 5-125 microns, 5-50 microns, preferably. The organic polymer film layer is made from at least one of a polyimide, a polyethylene terephthalate, a polybutylene terephthalate, a polysulfone, a polyphenylene sulfide, a polyether ether ketone, a polyphenyl ether, a polytetrafluoroethylene, a liquid crystal polymer and a polyparabanic acid. The adjusting layer is characterized by one of seven situations as follows. I) The adjusting layer is made from one of the following resin: thermoplastic polyimides, modified epoxy resins, modified acrylic acids, modified polyurethanes and modified phenolic resins, the thickness being 0.05-30 microns, 0.5-5 microns, preferably. II) Or, the adjusting layer is made from a matrix resin and a filler, the thickness being 0.05-30 microns, 0.5-6 microns, preferably; the matrix resin is at least one of thermoplastic polyimides, modified epoxy resins, modified acrylic acids, modified polyurethanes and modified phenolic resins; the filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin; and the volume percentage of the filler to the resin is 1-50%, 3-20%, preferably. III) Or, the adjusting layer is made from a resin and a catalyst solution, the thickness of the adjusting layer being 0.05-30 microns, 0.5-10 microns, preferably; and the resin is at least one of thermoplastic polyimides, modified epoxy resins, modified acrylic acids, modified polyurethanes and modified phenolic resins.

Preferably, the catalyst solution is a solution formed by salts of an iron group elements and/or a platinum group elements and an organic solvent.

Further preferably, the catalyst solution is a solution formed by a palladium salt and an ethyl alcohol or an acetone.

A manufacturing method for the adjusting layer as following: mixing the resin and the ethyl alcohol or the acetone solution of the palladium salt, curing at 160-180 DEG C, soaking a plate with the cured adjusting layer in a reducing agent solution (such as a sodium hypophosphite solution) at 60-80 DEG C, treating for 1-60 min, and taking out for drying.

Thus, some zero-valence Pds at least exist on the surface of the resin, and therefore, when the transition layer is formed on the adjusting layer, a binding force between the adjusting layer and the transition layer may be enhanced.

IV) Or, the adjusting layer is made from at least one of a coupling agent, a surfactant, an organic silicon and an organic low-polymer surface modifier, the thickness of the adjusting layer being 10-100 nm, 10-50 nm, preferably.

V) Or, the adjusting layer is a superposed layer of the adjusting layer I and the adjusting layer IV, the thickness being 0.05-30 microns, 0.5-5 microns, preferably.

VI) Or, the adjusting layer is a superposed layer of the adjusting layer II and the adjusting layer IV, the thickness being 0.05-30 microns, 0.5-6 microns, preferably.

VII) Or, the adjusting layer is a superposed layer of the adjusting layer III and the adjusting layer IV, the thickness being 0.05-30 microns, 0.5-10 microns, preferably. The peel strength between the organic polymer film layer and the transition layer is improved by means of the adjusting layer.

2) One or more transition layers are formed on the surface of the adjusting layer. The thickness of the transition layer is 0.01-0.5 micron (that is, when the transition layer is a single layer, the thickness of the single transition layer is 0.01-0.5 micron, when the number of the transition layer is more than one, the total thickness of the transition layer is 0.01-0.5 micron, and when the following embodiments involve the thickness limit of the transition layer, this definition is provided), 0.05-0.3 microns, preferably. The transition layer is made from one of a metal material, a ferrite and a carbon nanotube, wherein the metal material is one of these metal elementary substances: an aluminium, a titanium, a zinc, an iron, a nickel, a chromium, a cobalt, a copper, a silver, a gold and a molybdenum, or an alloy formed by at least two of these metal elementary substances. A forming mode of the transition layer is selected from a chemical plating mode, a PVD, a CVD, an evaporation plating, a sputter plating, an electroplating or a composite process.

3) A metal copper layer is formed on the surface of the transition layer. The thickness of the copper layer is 0.5-50 microns, 5-20 microns, preferably. A forming mode of the copper layer 4 is selected from a chemical plating mode, a PVD, a CVD, an evaporation plating, a sputter plating, an electroplating or a composite process thereof.

### Embodiment 2

An FCCL having a high peel strength includes an organic polymer film layer, an adjusting layer being disposed on at least one surface of the organic polymer film layer, one or more transition layers being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) At least one surface of an organic polymer film layer is modified. The thickness of the organic polymer film layer is 5-125 microns, 5-50 microns, preferably. The organic polymer film layer is made from at least one of a polyimide, a polyethylene terephthalate, a polybutylene terephthalate, a polysulfone, a polyphenylene sulfide, a polyether ether ketone, a polyphenyl ether, a polytetrafluoroethylene, a liquid crystal polymer and a polyparabanic acid. A surface modification method for the organic polymer film layer is a chemical etching process, a plasma treatment process, an ion injection process, a surface grafting process, an ion beam irradiation process, an excimer laser etching process or a composite process thereof, in order to improve the peel strength between the organic polymer film layer and the adjusting layer.

2) An adjusting layer is formed on the modified surface of the modified organic polymer film layer. The adjusting layer is characterized by one of seven situations as follows.

I) The adjusting layer is made from one of the following resins: thermoplastic polyimides, modified epoxy resins, modified acrylic acids, modified polyurethanes and modified phenolic resins, the thickness being 0.05-30 microns, 0.5-5 microns, preferably.

II) Or, the adjusting layer is made from a matrix resin and a filler, the thickness being 0.05-30 microns, 0.5-6 microns, preferably; the matrix resin is at least one of thermoplastic polyimides, modified epoxy resins, modified acrylic acids, modified polyurethanes and modified phenolic resins; the filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin; and the volume percentage of the filler to the resin is 1-50%, 3-20%, preferably.

III) Or, the adjusting layer is made from a resin and a catalyst solution, the thickness of the adjusting layer being 0.05-30 microns, 0.5-10 microns, preferably; and the resin is at least one of thermoplastic polyimides, modified epoxy resins, modified acrylic acids, modified polyurethanes and modified phenolic resins.

Preferably, the catalyst solution is a solution formed by salts of an iron group elements and/or a platinum group elements and an organic solvent.

Further preferably, the catalyst solution is a solution formed by a palladium salt and an ethyl alcohol or an acetone.

A manufacturing method for the adjusting layer as following: mixing the resin and the ethyl alcohol or the acetone solution of the palladium salt, curing at 160-180 DEG C, soaking a plate with the cured adjusting layer in a reducing agent solution (such as a sodium hypophosphite solution) at 60-80 DEG C, treating for 1-60 min, and taking out for drying.

Thus, some zero-valence Pds at least exists on the surface of the resin, and therefore, when the transition layer is formed on the adjusting layer, a binding force between the adjusting layer and the transition layer may be enhanced.

IV) Or, the adjusting layer is made from at least one of a coupling agent, a surfactant, an organic silicon and an organic low-polymer surface modifier, the thickness of the adjusting layer being 10-100 nm, 10-50 nm, preferably.

V) Or, the adjusting layer is a superposed layer of the adjusting layer I and the adjusting layer IV, the thickness being 0.05-30 microns, 0.5-5 microns, preferably.

VI) Or, the adjusting layer is a superposed layer of the adjusting layer II and the adjusting layer IV, the thickness being 0.05-30 microns, 0.5-6 microns, preferably.

VII) Or, the adjusting layer is a superposed layer of the adjusting layer III and the adjusting layer IV, the thickness being 0.05-30 microns, 0.5-10 microns, preferably. The peel strength between the organic polymer film layer and the transition layer is improved by means of the adjusting layer.

3) One or more transition layers are formed on the surface of the adjusting layer. The thickness of the transition layer is 0.01-0.5 micron, 0.05-0.3 microns, preferably. The transition layer is made from one of a metal material, a ferrite and a carbon nanotube, wherein the metal material is one of these metal elementary substances: an aluminium, a titanium, a zinc, an iron, a nickel, a chromium, a cobalt, a copper, a silver, a gold and a molybdenum, or an alloy formed by at least two of these metal elementary substances. A forming mode of the transition layer is selected from a chemical plating mode, a PVD, a CVD, an evaporation plating, a sputter plating, an electroplating or a composite process thereof.

4) A metal copper layer is formed on the surface of the transition layer. The thickness of the copper layer is 0.5-50 microns, 5-20 microns, preferably. A forming mode of the copper layer is selected from a chemical plating mode, a PVD, a CVD, an evaporation plating, a sputter plating, an electroplating or a composite process.

### Embodiment 3

An FCCL having a high peel strength includes an organic polymer film layer, an adjusting layer being disposed on at least one surface of the organic polymer film layer, one or more transition layers being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) An adjusting layer is formed on at least one surface of an organic polymer film layer. The thickness of the organic polymer film layer is 5-125 microns, 5-50 microns, preferably. The organic polymer film layer is made from at least one of a polyimide, a polyethylene terephthalate, a polybutylene terephthalate, a polysulfone, a polyphenylene sulfide, a polyether ether ketone, a polyphenyl ether, a polytetrafluoroethylene, a liquid crystal polymer and a polyparabanic acid.

The adjusting layer is characterized by one of seven situations as follows.

I) The adjusting layer is made from one of the following resins: thermoplastic polyimides, modified epoxy resins, modified acrylic acids, modified polyurethanes and modified phenolic resins, the thickness being 0.05-30 microns, 0.5-5 microns, preferably.

II) Or, the adjusting layer is made from a matrix resin and a filler, the thickness being 0.05-30 microns, 0.5-6 microns, preferably; the matrix resin is at least one of thermoplastic polyimides, modified epoxy resins, modified acrylic acids, modified polyurethanes and modified phenolic resins; the filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin; and the volume percentage of the filler to the resin is 1-50%, 3-20%, preferably.

III) Or, the adjusting layer is made from a resin and a catalyst solution, the thickness of the adjusting layer being 0.05-30 microns, 0.5-10 microns, preferably; and the resin is at least one of thermoplastic polyimides, modified epoxy resins, modified acrylic acids, modified polyurethanes and modified phenolic resins.

Preferably, the catalyst solution is a solution formed by salts of an iron group element and/or a platinum group element and an organic solvent.

Further preferably, the catalyst solution is a solution formed by a palladium salt and an ethyl alcohol or an acetone.

A manufacturing method for the adjusting layer as following: mixing the resin and the ethyl alcohol or the acetone solution of the palladium salt, curing at 160-180 DEG C, soaking a plate with the cured adjusting layer in a reducing agent solution (such as a sodium hypophosphite solution) at 60-80 DEG C, treating for 1-60 min, and taking out for drying.

Thus, some zero-valence Pds at least exist on the surface of the resin, and therefore, when the transition layer is formed on the adjusting layer, a binding force between the adjusting layer and the transition layer may be enhanced.

IV) Or, the adjusting layer is made from at least one of a coupling agent, a surfactant, an organic silicon and an organic low-polymer surface modifier, the thickness of the adjusting layer being 10-100 nm, 10-50 nm, preferably.

V) Or, the adjusting layer is a superposed layer of the adjusting layer I and the adjusting layer IV, the thickness being 0.05-30 microns, 0.5-5 microns, preferably.

VI) Or, the adjusting layer is a superposed layer of the adjusting layer II and the adjusting layer IV, the thickness being 0.05-30 microns, 0.5-6 microns, preferably.

VII) Or, the adjusting layer is a superposed layer of the adjusting layer III and the adjusting layer IV, the thickness being 0.05-30 microns, 0.5-10 microns, preferably. The peel strength between the organic polymer film layer and the transition layer is improved by means of the adjusting layer.

2) The surface of the adjusting layer is modified. A surface modification method for the adjusting layer is a chemical etching process, a plasma treatment process, an ion injection process, a surface grafting process, an ion beam irradiation process, an excimer laser etching process or a composite process. The peel strength between the adjusting layer and the transition layer is improved.

3) A transition layer is formed on the modified surface of the adjusting layer. The thickness of the transition layer is 0.01-0.5 micron, 0.05-0.3 microns, preferably. The transition layer is made from one of a metal material, a ferrite and a carbon nanotube, wherein the metal material is one of these metal elementary substances: an aluminium, a titanium, a zinc, an iron, a nickel, a chromium, a cobalt, a copper, a silver, a gold and a molybdenum, or an alloy formed by at least two of these metal elementary substances. A forming mode of the transition layer is selected from a chemical plating mode, a PVD, a CVD, an evaporation plating, a sputter plating, an electroplating or a composite process.

4) A metal copper layer is formed on the surface of the transition layer. The thickness of the copper layer is 0.5-50 microns, 5-20 microns, preferably. A forming mode of the copper layer 4 is selected from a chemical plating mode, a PVD, a CVD, an evaporation plating, a sputter plating, an electroplating or a composite process.

### Embodiment 4

An FCCL having a high peel strength includes an organic polymer film layer, an adjusting layer being disposed on at least one surface of the organic polymer film layer, one or more transition layers being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) At least one surface of an organic polymer film layer is modified. The thickness of the organic polymer film layer is 5-125 microns, 5-50 microns, preferably. The organic polymer film layer is made from at least one of a polyimide, a polyethylene terephthalate, a polybutylene terephthalate, a polysulfone, a polyphenylene sulfide, a polyether ether ketone, a polyphenyl ether, a polytetrafluoroethylene, a liquid crystal polymers and a polyparabanic acid. A surface modification method for the organic polymer film layer is a chemical etching process, a plasma treatment process, an ion injection process, a surface grafting process, an ion beam irradiation process, an excimer laser etching process or a composite process, in order to improve the peel strength between the organic polymer film layer and the adjusting layer.

2) An adjusting layer is formed on the modified surface of the modified organic polymer film layer. The adjusting layer is characterized by one of seven situations as follows.

I) The adjusting layer is made from one of the following resins: thermoplastic polyimides, modified epoxy resins, modified acrylic acids, modified polyurethanes and modified phenolic resins, the thickness being 0.05-30 microns, 0.5-5 microns, preferably.

II) Or, the adjusting layer is made from a matrix resin and a filler, the thickness being 0.05-30 microns, 0.5-6 microns, preferably; the matrix resin is at least one of thermoplastic polyimides, modified epoxy resins, modified acrylic acids, modified polyurethanes and modified phenolic resins; the filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin; and the volume percentage of the filler to the resin is 1-50%, 3-20%, preferably.

III) Or, the adjusting layer is made from a resin and a catalyst solution, the thickness of the adjusting layer being 0.05-30 microns, 0.5-10 microns, preferably; and the resin is at least one of thermoplastic polyimides, modified epoxy resins, modified acrylic acids, modified polyurethanes and modified phenolic resins.

Preferably, the catalyst solution is a solution formed by salts of an iron group element and/or a platinum group element and an organic solvent.

Further preferably, the catalyst solution is a solution formed by a palladium salt and an ethyl alcohol or an acetone.

A manufacturing method for the adjusting layer as following: mixing the resin and the ethyl alcohol or the acetone solution of the palladium salt, curing at 160-180 DEG C, soaking a plate with the cured adjusting layer in a reducing agent solution (such as a sodium hypophosphite solution) at 60-80 DEG C, treating for 1-60 min, and taking out for drying.

Thus, some zero-valence Pds at least exist on the surface of the resin, and therefore, when the transition layer is formed on the adjusting layer, a binding force between the adjusting layer and the transition layer may be enhanced.

IV) Or, the adjusting layer is made from at least one of a coupling agent, a surfactant, an organic silicon and an organic low-polymer surface modifier, the thickness being 10-100 nm, 10-50 nm, preferably.

V) Or, the adjusting layer is a superposed layer of the adjusting layer I and the adjusting layer IV, the thickness being 0.05-30 microns, 0.5-5 microns, preferably.

VI) Or, the adjusting layer is a superposed layer of the adjusting layer II and the adjusting layer IV, the thickness being 0.05-30 microns, 0.5-6 microns, preferably.

VII) Or, the adjusting layer is a superposed layer of the adjusting layer III and the adjusting layer IV, the thickness being 0.05-30 microns, 0.5-10 microns, preferably. The peel strength between the organic polymer film layer and the transition layer is improved by means of the adjusting layer.

3) The surface of the adjusting layer is modified. A surface modification method for the adjusting layer is a chemical etching process, a plasma treatment process, an ion injection process, a surface grafting process, an ion beam irradiation process, an excimer laser etching process or a composite process thereof. The peel strength between the adjusting layer and the transition layer is improved.

4) A transition layer is formed on the modified surface of the adjusting layer. The thickness of the transition layer is 0.01-0.5 micron, 0.05-0.3 microns, preferably. The transition layer is made from one of a metal material, a ferrite and a carbon nanotube, wherein the metal material is one of these metal elementary substances: an aluminium, a titanium, a zinc, an iron, a nickel, a chromium, a cobalt, a copper, a silver, a gold and a molybdenum, or an alloy formed by at least two of these metal elementary substances. A forming mode of the transition layer is selected from a chemical plating mode, a PVD, a CVD, an evaporation plating, a sputter plating, an electroplating or a composite process thereof.

5) A metal copper layer is formed on the surface of the transition layer. The thickness of the copper layer is 0.5-50 microns, 5-20 microns, preferably. A forming mode of the copper layer is selected from a chemical plating mode, a PVD, a CVD, an evaporation plating, a sputter plating, an electroplating or a composite process.

### Embodiment 5

An FCCL having a high peel strength includes a polymer film layer, an adjusting layer being disposed on the surface of one side of the organic polymer film layer, a transition layer being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) An adjusting layer is formed on the surface of one side of an organic polymer film layer, the organic polymer film layer is a polyimide thin film of 12.5 microns, and the adjusting layer is a modified polyurethane layer formed by a coating method, the thickness being 1 micron.

2) A transition layer is formed on the surface of the adjusting layer, the transition layer being a copper layer, formed by means of a sputtering method, of 0.02 micron.

3) A metal copper layer is formed on the surface of the transition layer. The thickness of the copper layer is 8 microns, and a forming mode is a composite process of a sputter plating and an electroplating. The peel strength of an FCCL is 10N/cm, and the peel strength is 9.2N/cm after solder float for 1 Os at 288 DEG C.

Wherein, the surface roughness of the organic polymer film layer is changed by means of the adjusting layer of which the thickness is 1 micron in Step 1), in order to improve the peel strength of the FCCL. Compared with conventional methods (a chemical etching, a surface grafting and the like), the disclosure improves the peel strength, does not affect the physical and mechanical properties of a product, and the surface of the adjusting layer is very stable, so the FCCL is suitable for large-batch coiled production.

Meanwhile, the inventor of the disclosure finds that before the adjusting layer is formed, the surface of the organic polymer film layer is treated or the surface of the adjusting layer is treated, so that the peel strength will be further improved. The surfaces of the organic polymer film layer and the adjusting layer are both treated, so that the peel strength is larger.

### Embodiment 6

An FCCL having a high peel strength includes a polymer film layer, an adjusting layer being disposed on the surface of one side of the organic polymer film layer, a transition layer being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) An adjusting layer is formed on the surface of one side of an organic polymer film layer, the organic polymer film layer is a polyimide thin film of 12.5 microns, the adjusting layer is made by a mixture of modified a polyurethane and a mica powder, the volume percentage of the mica powder to the modified polyurethane is 3%, and the thickness of the adjusting layer is 1 micron.

2) A transition layer is formed on the surface of the adjusting layer, the transition layer being a copper layer, formed by means of a sputtering method, of 0.02 micron.

3) A metal copper layer is formed on the surface of the transition layer. The thickness of the copper layer is 8 microns, and a composite process of a sputter plating and an electroplating is adopted. The peel strength of an FCCL is 11.5N/cm, and the peel strength is 10N/cm after solder float for 1 Os at 288 DEG C.

Compared with Embodiment 5, the present embodiment enables the surface roughness of the organic polymer film layer to be larger due to addition of a small amount of filler in the adjusting layer, and enables the peel strength of the FCCL to be larger.

Meanwhile, the inventor of the disclosure finds that before the adjusting layer is formed, the surface of the organic polymer film layer is treated or the surface of the adjusting layer is treated, so that the peel strength will be further improved. The surfaces of the organic polymer film layer and the adjusting layer are both treated, so that the peel strength is larger.

### Embodiment 7

An FCCL having a high peel strength includes a polymer film layer, an adjusting layer being disposed on the surface of one side of the organic polymer film layer, a transition layer being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) An adjusting layer is formed on the surface of one side of an organic polymer film layer, the organic polymer film layer is a polyimide thin film of 12.5 microns, the adjusting layer is made from a mixture of an ethyl alcohol solution of a palladium dichloride and a polyurethane resin, and a manufacturing method for the adjusting layer as following: mixing the resin and the ethyl alcohol solution of the palladium dichloride, curing at 160-180 DEG C, soaking a plate with the cured adjusting layer in a reducing agent solution (such as a sodium hypophosphite solution) at 60-80 DEG C, and treating for 1-60 min, the thickness of the adjusting layer being 5 microns finally.

2) A transition layer is formed on the surface of the adjusting layer, the transition layer being a copper layer of 0.02 micron.

3) A metal copper layer is formed on the surface of the transition layer. The copper layer of which the thickness is 8 microns is formed using an electroplating process. The peel strength of an FCCL is 11.8N/cm, and the peel strength is 10N/cm after solder float for 1 Os at 288 DEG C.

Compared with Embodiment 6, the present embodiment has the advantages that zero-valence Pds are at least distributed on the surface of the adjusting layer, the transition layer is formed, and then the metal copper layer is formed. This method may increase a binding force between the adjusting layer and the transition layer, thus improving the peel strength of the FCCL.

Meanwhile, the inventor of the disclosure finds that before the adjusting layer is formed, the surface of the organic polymer film layer is treated or the surface of the adjusting layer is treated, so that the peel strength will be further improved. the surfaces of the organic polymer film layer and the adjusting layer are both treated, so that the peel strength is larger.

### Embodiment 8

An FCCL having a high peel strength includes a polymer film layer, an adjusting layer being disposed on the surface of one side of the organic polymer film layer, a transition layer being disposed on the other side of the adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) An adjusting layer is formed on the surface of one side of an organic polymer film layer, the organic polymer film layer is a polyimide thin film of 12.5 microns, the adjusting layer is an adjusting layer, formed by an organic low polymer surface modifier, of 0.01 micron, and the peel strength between the organic polymer film layer and a transition layer is improved by means of the adjusting layer.

2) A transition layer is formed on the surface of the adjusting layer, the transition layer being a copper layer, formed by means of a sputtering method, of 0.02 micron.

3) A metal copper layer is formed on the surface of the transition layer. The thickness of the copper layer is 8 microns, and a composite process of a sputter plating and an electroplating is adopted. The peel strength of an FCCL is 9.9N/cm, and the peel strength is 8N/cm after solder float for 1 Os at 288 DEG C.

Wherein, the surface of the organic polymer film layer is coated with an organic low polymer surface modifier of 0.01 micron in Step 1). The significance lies in that surface polar groups of the organic polymer film layer are increased by means of a chemical method, thus improving the peel strength of the FCCL.

Meanwhile, the inventor of the disclosure finds that before the adjusting layer is formed, the surface of the organic polymer film layer is treated or the surface of the adjusting layer is treated, so that the peel strength will be further improved. The surfaces of the organic polymer film layer and the adjusting layer are both treated, so that the peel strength is larger.

### Embodiment 9

An FCCL having a high peel strength includes a polymer film layer, a first adjusting layer being disposed on the surface of one side of the organic polymer film layer, a second adjusting layer being disposed on the other side of the first adjusting layer, a transition layer being disposed on the other side of the second adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) A first adjusting layer is formed on the surface of an organic polymer film layer, the organic polymer film layer is a polyimide thin film of 12.5 microns, the first adjusting layer is an adjusting layer with a thickness being 1 Onms, formed by a silane coupling agent, and the peel strength between the organic polymer film layer and a second adjusting layer is improved by means of the first adjusting layer.

2) A second adjusting layer is formed on the surface of the first adjusting layer, the second adjusting layer being modified polyurethane, and the thickness being 3 microns. The peel strength between the organic polymer film layer and a transition layer is improved by means of the first adjusting layer and the second adjusting layer.

3) A transition layer is formed on the surface of the second adjusting layer, the transition layer being a copper layer, formed by means of a sputtering method, of 0.02 micron.

4) A metal copper layer is formed on the surface of the transition layer. The thickness of the copper layer is 8 microns, and a composite process of a sputter plating and an electroplating is adopted. The peel strength of an FCCL is 12.5N/cm, and the peel strength is 10N/cm after solder float for 1 Os at 288 DEG C.

Wherein, the surface of the organic polymer film layer is coated with a silane coupling agent of 10 nms to form the first adjusting layer in Step 1), and then the surface of the first adjusting layer is coated with the modified polyurethane in Step 2). The significance lies in that surface polar groups of the organic polymer film layer are increased by means of a chemical method, the peel strength between the organic polymer film layer and the second adjusting layer is improved, the surface roughness of the organic polymer film layer is changed by disposing the second adjusting layer, and the aim of improving the peel strength of the FCCL is achieved finally.

Meanwhile, the inventor of the disclosure finds that before the adjusting layer is formed, the surface of the organic polymer film layer is treated or the surface of the second adjusting layer is treated, so that the peel strength will be further improved. The surfaces of the organic polymer film layer and the second adjusting layer are both treated, so that the peel strength is larger.

### Embodiment 10

An FCCL having a high peel strength includes a polymer film layer, a first adjusting layer being disposed on the surface of one side of the organic polymer film layer, a second adjusting layer being disposed on the other side of the first adjusting layer, a transition layer being disposed on the other side of the second adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) A first adjusting layer is formed on the surface of an organic polymer film layer, the organic polymer film layer is a polyimide thin film of 12.5 microns, the first adjusting layer is an adjusting layer with a thickness being 10 nms, formed by a silane coupling agent, and the peel strength between the organic polymer film layer and a second adjusting layer is improved by means of the first adjusting layer.

2) A second adjusting layer is formed on the surface of the first adjusting layer, the second adjusting layer is made from a mixture of a modified polyurethane and a mica powder, the volume percentage of the mica powder to the modified polyurethane is 3%, and the thickness of the second adjusting layer is 3 microns. The peel strength between the organic polymer film layer and a transition layer is improved by means of the first adjusting layer and the second adjusting layer.

3) A transition layer is formed on the surface of the second adjusting layer, the transition layer being a copper layer, formed by means of a sputtering method, of 0.02 micron.

4) A metal copper layer is formed on the surface of the transition layer. The thickness of the copper layer is 8 microns, and a composite process of a sputter plating and an electroplating is adopted. The peel strength of an FCCL is 13.2N/cm, and the peel strength is 11N/cm after solder float for 1 Os at 288 DEG C.

Wherein, the surface of the organic polymer film layer is coated with a silane coupling agent of 10 nm to form the first adjusting layer in Step 1), and then the surface of the first adjusting layer is coated with the modified polyurethane containing filler in Step 2). The significance lies in that surface polar groups of the organic polymer film layer are increased by means of a chemical method, the peel strength between the organic polymer film layer and the second adjusting layer is improved, and the surface roughness of the organic polymer film layer is changed by disposing the second adjusting layer. Compared with Embodiment 8, the present embodiment enables the surface roughness of the organic polymer film layer to be larger due to addition of a small amount of filler in the second adjusting layer, and enables the peel strength of the FCCL to be higher.

Meanwhile, the inventor of the disclosure finds that before the adjusting layer is formed, the surface of the organic polymer film layer is treated or the surface of the second adjusting layer is treated, so that the peel strength will be further improved. The surfaces of the organic polymer film layer and the second adjusting layer are both treated, so that the peel strength is larger.

### Embodiment 11

An FCCL having a high peel strength includes a polymer film layer, a first adjusting layer being disposed on the surface of one side of the organic polymer film layer, a second adjusting layer being disposed on the other side of the first adjusting layer, a transition layer being disposed on the other side of the second adjusting layer, and a copper layer being disposed on the other side of the transition layer, wherein the adjusting layer may improve the peel strength between the organic polymer film layer and a metal layer.

A manufacturing method for an FCCL having a high peel strength includes the specific manufacturing steps as follows.

1) A first adjusting layer is formed on the surface of an organic polymer film layer, the organic polymer film layer is a polyimide thin film of 12.5 microns, the first adjusting layer is an adjusting layer with a thickness being 1 Onms, formed by a silane coupling agent, and the peel strength between the organic polymer film layer and a second adjusting layer is improved by means of the first adjusting layer.

2) A second adjusting layer is formed on the surface of the first adjusting layer, the second adjusting layer is made from a mixture of an ethyl alcohol solution of a palladium dichloride and a polyurethane resin, and a manufacturing method for the adjusting layer as following: mixing the resin and the ethyl alcohol solution of the palladium dichloride, curing at 160-180 DEG C, soaking a plate with the cured adjusting layer in a reducing agent solution (such as a sodium hypophosphite solution) at 60-80 DEG C, treating for 1-60 min, and then taking out for drying, the thickness of the adjusting layer being 5 microns finally.

3) A transition layer is formed on the surface of the second adjusting layer, the transition layer being a copper layer of 0.02 micron.

4) A metal copper layer is formed on the surface of the transition layer. The copper layer of which the thickness is 8 microns is formed using an electroplating process. The peel strength of an FCCL is 13.7N/cm, and the peel strength is 11N/cm after solder float for 1 Os at 288 DEG C.

Wherein, the surface of the organic polymer film layer is coated with a silane coupling agent of 10 nm to form the first adjusting layer in Step 1), and then a modified polyurethane containing a catalyst is formed on the surface of the first adjusting layer in Step 2). The significance lies in that surface polar groups of the organic polymer film layer are increased by means of a chemical method, the peel strength between the organic polymer film layer and the second adjusting layer is improved, zero-valence Pds are at least distributed on the surface of the second adjusting layer, the transition layer is formed, and then the metal copper layer is formed. This method may increase a binding force between the adjusting layer and the transition layer, thus improving the peel strength of the FCCL.

Meanwhile, the inventor of the disclosure finds that before the adjusting layer is formed, the surface of the organic polymer film layer is treated or the surface of the second adjusting layer is treated, so that the peel strength will be further improved. The surfaces of the organic polymer film layer and the second adjusting layer are both treated, so that the peel strength is larger.

In the above embodiments, any limits to a copper layer protection method are not made. An anti-oxidation protection layer may be disposed on the surface of the metal copper layer according to actual requirements, or the metal copper layer is roughened, so as to facilitate laser boring. Any small corrections, equivalent changes and modifications made for the above embodiments according to the technical essence of the disclosure and the copper layer protection method shall fall within the scope of the technical solutions of the disclosure.

### Contrasting Example 1

Coating and laminating methods are adopted. The surface of a copper foil of 12 microns is coated with a thermoplastic polyimide solution (TPI) of 5 microns, a PI of 12.5 microns is laminated with copper foil and cured, and the peel strength of an FCCL product is up to 11.1N/cm. Compared with the peel strength of Embodiment 5 to Embodiment 11, the peel strength is lower than that of Embodiment 6-7 and Embodiment 9-11, and is slightly higher than that of Embodiment 5 and Embodiment 8. However, the minimum thickness of the copper foil is 12 microns. When an ultrathin copper foil is coated or laminated, folds are easily caused or even ruptures are generated, and it is difficult to coat or laminate using a thinner copper foil, such that application to high-grade precise electronic products such as liquid crystal (plasma) displays and liquid crystal (plasma) televisions based on an HDI technology and a COF technology is certainly limited. There are technical bottlenecks of the coating and laminating methods. However, FCCLs produced in Embodiment 5 to Embodiment 9 not only is high in peel strength, but also is applicable to an ultrathin line and an HDI circuit board due to the fact that the thickness of the copper foil is only 8 microns.

### Contrasting Example 2

A plating method is adopted. The surface of a PI film is modified in an ion injection mode, the surface activity is improved, the thickness of the PI film is 12.5 microns, a metal bottoming layer (a nickel copper alloy layer of 0.02 micron) is formed on the modified surface of the PI film by means of a sputtering method, and a copper foil of 8 microns is electroplated finally, the peel strength being only 6N/cm. Compared with the peel strength of Embodiment 5 to Embodiment 11, the peel strength is extremely low, and cannot meet use requirements.

TABLE 1

| | Embodiment | | | | | | | | |
|---|---|---|---|---|---|---|---|---|---|
| | Embodiment | Embodiment | Embodiment | Embodiment | Embodiment | Embodiment | Embodiment | Contrasting | Contrasting |
| | 5 | 6 | 7 | 8 | 9 | 10 | 11 | example 1 | example 2 |
| Peel | 10 | 11.5 | 11.8 | 9.9 | 12.5 | 13.2 | 13.7 | 11.1 | 6 |
| strength | | | | | | | | | |
| (N/cm) | | | | | | | | | |

1. A flexible copper clad laminate having a high peel strength, comprising the following layer structures: an organic polymer film layer, an adjusting layer disposed on at least one surface of the organic polymer film layer, a transition layer disposed on the surface of the adjusting layer, and a copper layer disposed on the surface of the transition layer, wherein the number of the transition layer is one or more.

2. The flexible copper clad laminate having a high peel strength according to claim 1, wherein the thickness of the organic polymer film layer is 5-125 microns; the organic polymer film layer is made from at least one of a polyimide, a polyethylene terephthalate, a polybutylene terephthalate, a polysulfone, a polyphenylene sulfide, a polyether ether ketone, a polyphenylene ether, a polytetrafluoroethylene, a liquid crystal polymer and a polyparabanic acid.

3. The flexible copper clad laminate having a high peel strength according to claim 1, wherein the adjusting layer is one of the following adjusting layers listed from I to VII:
I) the adjusting layer is made from at least one of thermoplastic polyimides, modified epoxy resins, modified acrylic acids, modified polyurethanes and modified phenolic resins, the thickness being 0.05-30 microns;
II) the adjusting layer is made from a mixture of matrix resin and filler, the thickness of the adjusting layer being 0.05-30 microns; the matrix resin is at least one of thermoplastic polyimides, modified epoxy resins, modified acrylic acids, modified polyurethanes and modified phenolic resins; the filler is at least one of a silicon dioxide, an aluminium hydroxide, a calcium carbonate, a titanium dioxide, an aluminium oxide, a magnesium hydroxide, a magnesium carbonate, a silicon carbide, a barium sulphate, a mica powder, a silica powder, a talcum powder and a kaolin, the volume percentage of the filler to the resin being 1-50%;
III) the adjusting layer is made from a resin and a catalyst solution, the thickness of the adjusting layer being 0.05-30 microns; the resin is at least one of thermoplastic polyimides, modified epoxy resins, modified acrylic acids, modified polyurethanes and modified phenolic resins;
IV) the adjusting layer is made from at least one of a coupling agent, a surfactant, an organic silicon and an organic low-polymer surface modifier, the thickness of the adjusting layer being 10-100 nm;
V) the adjusting layer is a superposed layer of the adjusting layer I and the adjusting layer IV, the thickness being 0.05-30 microns;
VI) the adjusting layer is a superposed layer of the adjusting layer II and the adjusting layer IV, the thickness being 0.05-30 microns; and
VII) the adjusting layer is a superposed layer of the adjusting layer III and the adjusting layer IV, the thickness being 0.05-30 microns.

4. The flexible copper clad laminate having a high peel strength according to claim 1, wherein when the transition layer is a single layer, the thickness of the transition layer is 0.01-0.5 microns; when the number of the transition layer is more than one, the total thickness of the transition layer is 0.01-0.5 microns; the transition layer is made from one of a metal material, a ferrite and a carbon nanotube, wherein, the metal material being one of these metal elementary substances: an aluminium, a titanium, a zinc, an iron, a nickel, a chromium, a cobalt, a copper, a silver, a gold and a molybdenum, or an alloy formed by at least two of these metal elementary substances; a forming mode of the transition layer is selected from a chemical plating mode, a physical vacuum deposition, a chemical vapour deposition, an evaporation plating, a sputter plating, an electroplating or a composite process thereof; and a forming mode of the copper layer is selected from a chemical plating mode, a physical vacuum deposition, a chemical vapour deposition, an evaporation plating, a sputter plating, an electroplating or a composite process.

5. A manufacturing method for the flexible copper clad laminate having a high peel strength according to claim 1, comprising the following steps:
1) forming an adjusting layer on at least one surface of an organic polymer film layer;
2) forming one or more transition layers on the surface of the adjusting layer;
3) forming a metal copper layer on the surface of the transition layer.

6. A manufacturing method for the flexible copper clad laminate having a high peel strength according to claim 1, comprising the following steps:
1) modifying at least one surface of an organic polymer film layer, and forming an adjusting layer on at least one surface of the modified organic polymer film layer;
2) forming one or more transition layers on the surface of the adjusting layer;
3) forming a metal copper layer on the surface of the transition layer.

7. A manufacturing method for the flexible copper clad laminate having a high peel strength according to claim 1, comprising the following steps:
1) forming an adjusting layer on at least one surface of an organic polymer film layer;
2) modifying the surface of the adjusting layer;
3) forming one or more transition layers on the modified surface of the adjusting layer;
4) forming a metal copper layer on the surface of the transition layer.

8. A manufacturing method for the flexible copper clad laminate having a high peel strength according to claim 1, comprising the following steps:
1) modifying at least one surface of an organic polymer film layer;
2) forming an adjusting layer on at least one surface of the modified organic polymer film layer;
3) modifying the surface of the adjusting layer;
4) forming one or more transition layers on the modified surface of the adjusting layer;
5) forming a metal copper layer on the surface of the transition layer.

9. The manufacturing method for the flexible copper clad laminate having a high peel strength according to claim 8, wherein a surface modification method for the organic polymer film layer or the adjusting layer is selected from a chemical etching process, a plasma treatment process, an ion injection process, a surface grafting process, an ion beam irradiation process, an excimer laser etching process or a composite process thereof.

10. The manufacturing method for the flexible copper clad laminate having a high peel strength according to claim 8, further comprising: after the metal copper layer is formed, forming an anti-oxidation protection layer on the surface of the metal copper layer as required; or, roughening the metal copper layer.

11. The manufacturing method for the flexible copper clad laminate having a high peel strength according to claim 5, further comprising: after the metal copper layer is formed, forming an anti-oxidation protection layer on the surface of the metal copper layer as required; or, roughening the metal copper layer.

12. The manufacturing method for the flexible copper clad laminate having a high peel strength according to claim 6, wherein a surface modification method for the organic polymer film layer is selected from a chemical etching process, a plasma treatment process, an ion injection process, a surface grafting process, an ion beam irradiation process, an excimer laser etching process or a composite process thereof.

13. The manufacturing method for the flexible copper clad laminate having a high peel strength according to claim 6, further comprising: after the metal copper layer is formed, forming an anti-oxidation protection layer on the surface of the metal copper layer as required; or, roughening the metal copper layer.

14. The manufacturing method for the flexible copper clad laminate having a high peel strength according to claim 7, wherein a surface modification method for the adjusting layer is selected from a chemical etching process, a plasma treatment process, an ion injection process, a surface grafting process, an ion beam irradiation process, an excimer laser etching process or a composite process thereof.

15. The manufacturing method for the flexible copper clad laminate having a high peel strength according to claim 7, further comprising: after the metal copper layer is formed, forming an anti-oxidation protection layer on the surface of the metal copper layer as required; or, roughening the metal copper layer.
